(19) United States
(12) Patent Application Publication
(10) Pub. No.: US 2026/0095167 A1
(43) Pub. Date: Apr. 2, 2026

(54) PHASE SHIFTER CIRCUIT OF OPTICAL ENCODER HAVING PHASE SHIFT RESISTORS AND ATTENUATION RESISTORS

(71) Applicant: PIXART IMAGING INC., Hsin-Chu County (TW)

(72) Inventor: Chung-Min THOR, Penang (MY)

(21) Appl. No.: 18/900,896

(22) Filed: Sep. 30, 2024

(51) Int. Cl. H03K 5/13; H03K 5/00; H03K 5/24

(52) U.S. Cl. CPC H03K 5/13; H03K 5/24; H03K 2005/00019; H03K 2005/00286

(57) ABSTRACT

There is provided a phase shifter circuit of an optical encoder. The phase shifter circuit receives a first signal, a second signal, a third signal and a fourth signal sequentially having a 90-degree phase shift, and includes a resistor string and an attenuation circuit. The resistor string is used to correct phases of the first, second, third and fourth signals. The attenuation circuit is used to equalize amplitudes of phase-corrected signals outputted by the resistor string.

### FIELD OF THE DISCLOSURE

This disclosure generally relates to an optical encoder and, more particularly, to a phase shifter circuit of an incremental optical encoder that calibrates a phase deviation of incremental signals using phase shift resistors, and equalizes amplitudes of phase-corrected signals using attenuation resistors.

### BACKGROUND OF THE DISCLOSURE

Referring to FIG. 1, it is a block diagram of a conventional optical encoder that includes a light source 11, an encoding medium 13, photodiodes 15, a trans-impedance amplifier (TIA) 17 and a comparator 19. The photodiodes 15 detect light emitted from the light source 11 and modulated by the encoding medium 13 to output four signals A, B, A′ and B′ sequentially having a 90-degree phase shift via the TIA 17. The comparator 19 compares the four signals A, B, A′ and B′ to output two output signals CHA and CHB.

FIG. 2 is a timing diagram of the two output signals CHA and CHB. It is seen from FIG. 2 that voltage levels of the two output signals CHA and CHB have a combination of four states within one period of the encoding medium 13. Accordingly, four positions of the encoding medium 13 can be indicated.

In a 3-channel incremental optical encoder, a third signal called index signal is generated from the second track in a code wheel. The index signal is used as a homing signal in a motor feedback system. However, if components of the 3-channel incremental optical encoder have a spatial deviation therebetween, the index signal can have a phase deviation from incremental AB signals, i.e. CHA and CHB as shown in FIG. 2.

FIG. 3A shows a signal timing diagram of incremental AB signals and index signals at a normal spatial arrangement. FIG. 3B shows a signal timing diagram of the incremental AB signals and the index signals, in which an index slit for generating the index signals has a positive spatial deviation. FIG. 3C shows a signal timing diagram of the incremental AB signals and the index signals, in which an index slit for generating the index signals has a negative spatial deviation. It is seen from FIGS. 3B and 3C that two peaks appear in the index signals, and the two peaks will affect the determining of absolute positions.

### SUMMARY

Accordingly, the present disclosure provides a phase shifter circuit of an incremental optical encoder including phase-delay resistor strings and attenuation circuits. The phase-delay resistor strings calibrate a phase deviation of four signals outputted by photodiodes by selecting proper switching devices in the phase-delay resistor strings. The attenuation circuits equalize amplitudes of phase-corrected signals outputted by the phase-delay resistor strings.

The present disclosure provides a phase shifter circuit of an optical encoder. The phase shifter circuit receives a first signal, a second signal, a third signal and a fourth signal sequentially having a 90-degree phase shift. The phase shifter circuit includes a resistor string and an attenuation circuit. The resistor string includes 4 resistors cascaded together, and two ends of the resistor string receive two signals among the first to fourth signals, respectively. The attenuation circuit includes a first resistor, a second resistor and a third resistor, wherein a first end of the first resistor is coupled to the resistor string to receive a 0-degree phase-corrected signal via a first switch or to receive a 90-degree phase-corrected signal via a fifth switch, and a second end of the first resistor is coupled to an output terminal of the attenuation circuit via a sixth switch, a first end of the second resistor is coupled to a reference voltage, and a second end of the second resistor is coupled to the output terminal via the sixth switch, and a first end of the third resistor is coupled to the reference voltage, and a second end of the third resistor is coupled to the output terminal via a seventh switch.

The present disclosure further provides a phase shifter circuit of an optical encoder. The phase shifter circuit receives a first signal, a second signal, a third signal and a fourth signal sequentially having a 90-degree phase shift. The phase shifter circuit includes a resistor string and an attenuation circuit. The resistor string includes 4 resistors cascaded together, and two ends of the resistor string receive two signals among the first to fourth signals, respectively. The attenuation circuit includes a first resistor, a second resistor and a third resistor, wherein a first end of the first resistor is coupled to the resistor string to receive a 0-degree phase-corrected signal via a first switch or to receive a 90-degree phase-corrected signal via a fifth switch, and a second end of the first resistor is coupled to an output terminal of the attenuation circuit via a sixth switch, a first end of the second resistor is coupled to a reference voltage, and a second end of the second resistor is coupled to the output terminal via an eighth switch and the sixth switch, and a first end of the third resistor is coupled to the second end of the second resistor via a ninth switch, and a second end of the third resistor is coupled to the output terminal via a seventh switch.

The present disclosure further provides a phase shifter circuit of an optical encoder. The phase shifter circuit receives a first signal, a second signal, a third signal and a fourth signal sequentially having a 90-degree phase shift. The phase shifter circuit includes four resistor strings and four attenuation circuits. Each resistor string includes 4 resistors cascaded together, and two ends of each resistor string being configured to receive two signals among the first to fourth signals, respectively. Each attenuation circuit includes a first resistor, a second resistor and a third resistor, and each attenuation circuit is used to attenuate amplitudes of a 0-degree phase-corrected signal, a 22.5-degree phase-corrected signal, a 67.5-degree phase-corrected signal or a 90-degree phase-corrected signal to be identical to a 45-degree phase-corrected signal outputted by a corresponding resistor string.

### BRIEF DESCRIPTION OF DRAWINGS

Other objects, advantages, and novel features of the present disclosure will become more apparent from the following detailed description when taken in conjunction with the accompanying drawings.

FIG. 1 is a block diagram of a conventional optical encoder.

FIG. 2 is a timing diagram of output signals of the optical encoder in FIG. 1.

FIG. 3A is a timing diagram of incremental AB signals and index signals at a normal spatial arrangement.

FIG. 3B is a timing diagram of the incremental AB signals and the index signals in which an index slit has a positive position deviation in a tangential direction of an encoding medium.

FIG. 3C is a timing diagram of the incremental AB signals and the index signals in which an index slit has a negative position deviation in a tangential direction of an encoding medium.

FIG. 4 is a schematic diagram of an incremental optical encoder according to one embodiment of the present disclosure.

FIG. 5 is a schematic diagram of an operation of a phase shifter circuit according to one embodiment of the present disclosure.

FIG. 6 is a schematic diagram of a phase shifter circuit according to one embodiment of the present disclosure.

FIG. 7 is a schematic diagram of amplitude attenuation of phase-corrected signals caused by a resistor string of a phase shifter circuit according to one embodiment of the present disclosure.

FIG. 8 is a schematic diagram of a phase shifter circuit according to a first embodiment of the present disclosure.

FIG. 9 is a schematic diagram of switch operation of the phase shifter circuit in FIGS. 6 and 8.

FIG. 10 is a schematic diagram of phase-corrected signals after the amplitude compensation by a phase shifter circuit according to the embodiment of the present disclosure.

FIG. 11 is a schematic diagram of a phase shifter circuit according to a second embodiment of the present disclosure.

FIG. 12 is a schematic diagram of switch operation of the phase shifter circuit in FIGS. 6 and 11.

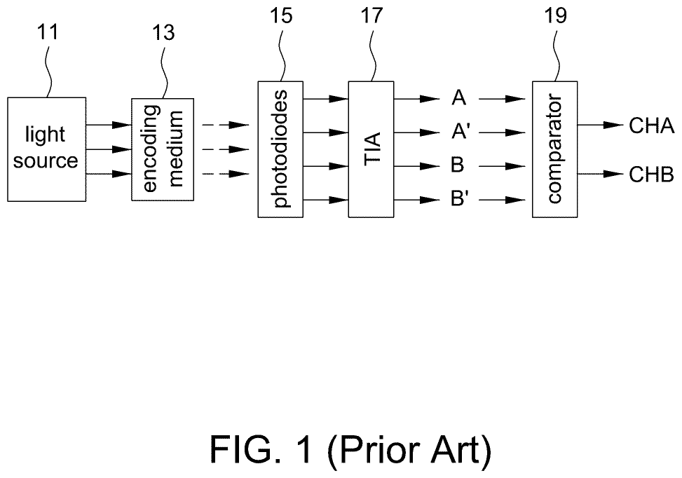

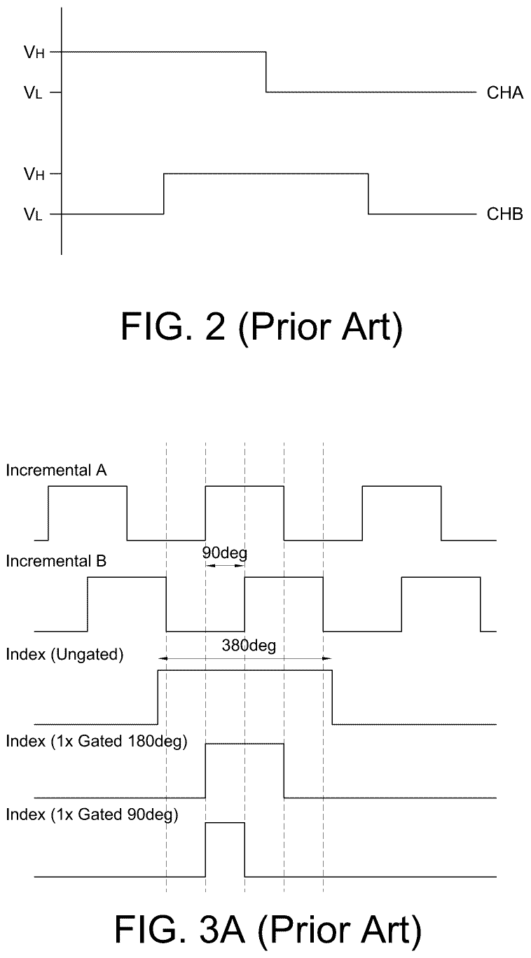

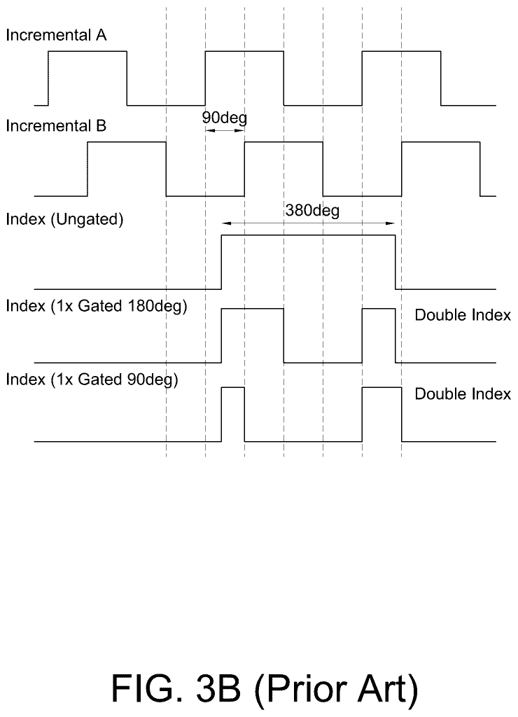

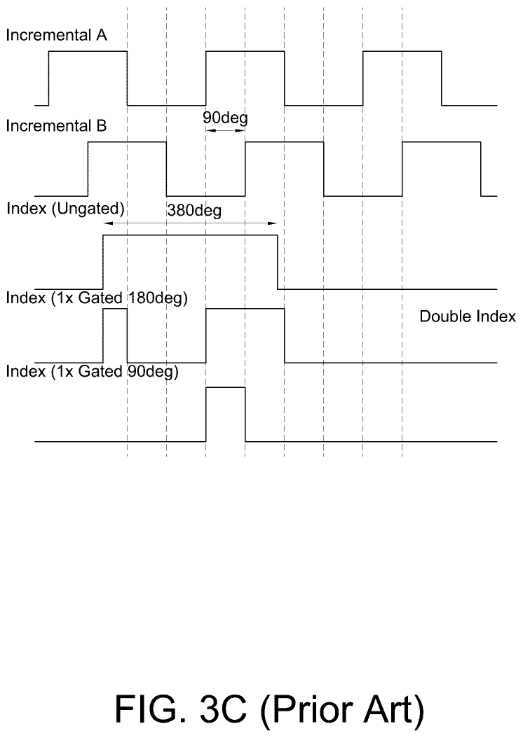

### DETAILED DESCRIPTION OF THE DISCLOSURE

It should be noted that, wherever possible, the same reference numbers will be used throughout the drawings to refer to the same or like parts.

One objective of the present disclosure is to provide a phase shifter circuit of an optical encoder for correcting a phase shift of incremental signals, e.g. between CHAB and an index signal by adopting phase-delay resistor strings to calibrate a phase deviation of four signals outputted by photodiodes. An attenuation circuit connected behind phase-delay resistor strings is further provided to compensate a signal attenuation of tape-out signals (or called phase-corrected signals) from the phase-delay resistor strings.

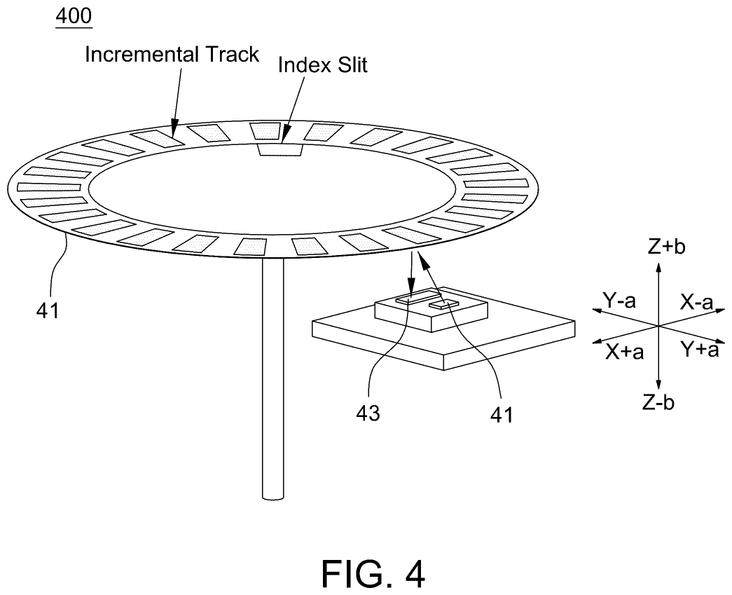

Please refer to FIG. 4, it is a schematic diagram of an incremental optical encoder 400 according to one embodiment of the present disclosure. The incremental optical encoder 400 is shown as a reflective type optical encoder as an example, but the present disclosure is not limited thereto. The phase shifter circuit of the present disclosure mentioned below is also adaptable to a transmissive type optical encoder.

The incremental optical encoder 400 includes an encoding medium 41, a light source 41 and photodiodes 43. The light source 41 is a light emitting diode or a laser diode. The encoding medium 41 is arranged (e.g., attached, sputtered or painted, but not limited to) with an incremental track and an index slit. The incremental track is used to generate a first incremental signal (e.g., CHA) and a second incremental signal (e.g., CHB), e.g., referring to FIG. 2. The index slit is used to generate an index signal.

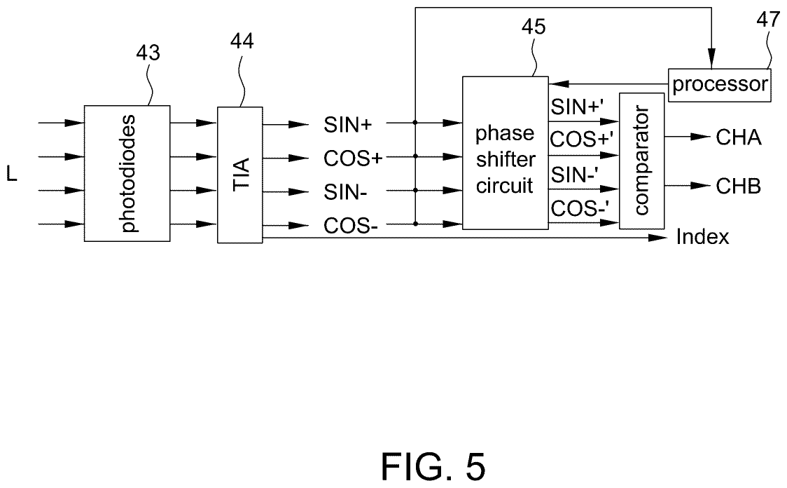

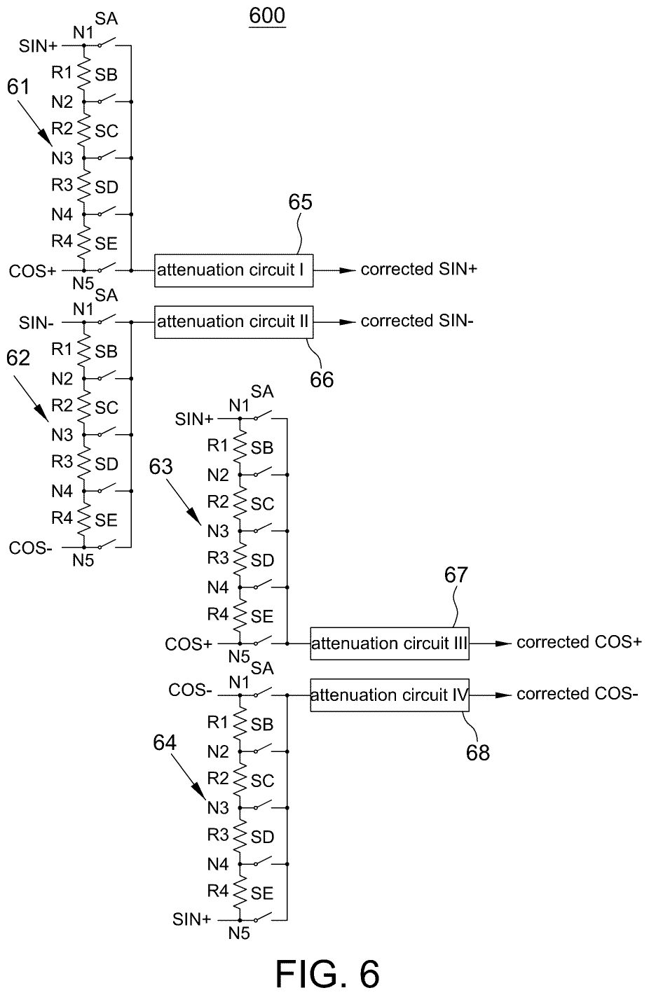

Please refer to FIG. 5, it is a schematic diagram of an operation of an optical encoder 400 according to one embodiment of the present disclosure. The encoding medium is not shown in FIG. 5. The phase shifter circuit 45 is used to receive a first signal (e.g., shown as SIN+), a second signal (e.g., shown as COS+), a third signal (e.g., shown as SIN−) and a fourth signal (e.g., shown as COS−) sequentially having a 90-degree phase shift from the photodiodes 43 and a trans-impedance amplifier (shown as TIA) 44. In one aspect, the phase shifter circuit 45 outputs corrected signals (e.g., shown as SIN+′, COS+′, SIN−′ and COS−′) to a comparator which generates CHA and CHB according to the corrected first, second, third and fourth signals (e.g., corrected SIN+, corrected COS+, corrected SIN− and corrected COS− shown in FIG. 6). The processor 47, e.g., a micro controller unit (MCU), an application specific integrated circuit (ASIC) or a field programmable gate array (FPGA), controls operation of the switching devices and switches mentioned below for the phase calibration.

In the present disclosure, the phase shifter circuit 45 is used to correct phase shift of CHA and CHB with respect to Index signal.

Details of the photodiodes 43 and the TIA 44 to generate the first, second third and fourth signals are known to the art, and thus are not described herein. Details of the comparator to generate the CHA and CHB according to the corrected first, second third and fourth signals are known to the art, e.g., by comparing amplitudes between SIN+′ and COS−′ and between SIN+′ and COS+′, but not limited to, and thus are not described herein. A further objective of the present disclosure is to correct a phase deviation of the first, second third and fourth signals and to adjust amplitudes of phase-corrected signals to be identical.

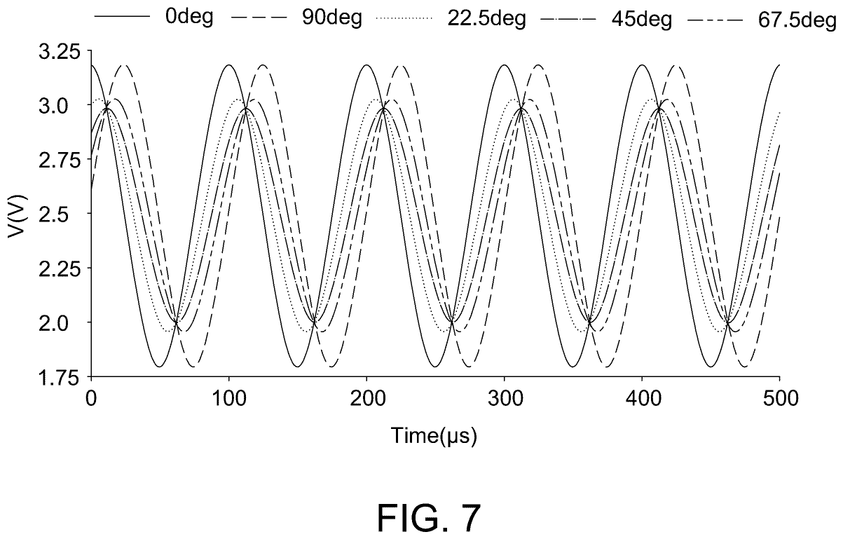

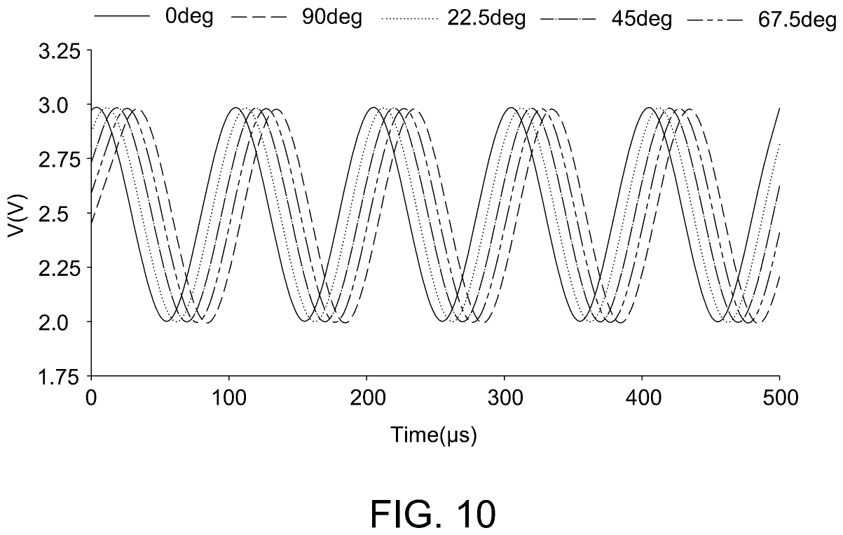

Please refer to FIG. 6, it is a schematic diagram of a phase shifter circuit 600 according to one embodiment of the present disclosure. The phase shifter circuit 600 includes a first resistor string 61, a second resistor string 62, a third resistor string 63, a fourth resistor string 64, a first attenuation circuit 65, a second attenuation circuit 66, a third attenuation circuit 67 and a fourth attenuation circuit 68. Each attenuation circuit is corresponding to one resistor string. Each attenuation circuit is used to attenuate amplitudes of a 0-degree phase-corrected signal, a 22.5-degree phase-corrected signal, a 67.5-degree phase-corrected signal and a 90-degree phase-corrected signal to be identical to a 45-degree phase-corrected signal, e.g., amplitudes from FIG. 7 to amplitudes shown in FIG. 10. In one aspect, the amplitude of the 45-degree phase-corrected signal is previously determined according to requirement.

In one aspect, the 22.5-degree phase-corrected signal and the 67.5-degree phase-corrected signal are attenuated by a factor 0.9242, i.e. 1/1.082, and the 0-degree phase-corrected signal and the 90-degree phase-corrected signal are attenuated by a factor 0.7072, i.e. 1/1.414 based on Table II below.

The first resistor string 61, the second resistor string 62, the third resistor string 63 and the fourth resistor string 61 respectively have 4 resistors (e.g., shown as R1, R2, R3 and R4) cascaded together, and two ends (e.g., shown as N1 and N5) of each of the resistor strings 61 to 64 are used to respectively receive two signals among the first to fourth signals, e.g., shown as the first signal SIN+ and the second signal COS+, the third signal SIN− and the fourth signal COS−, the second signal COS+ and the third signal SIN−, or the fourth signal COS− and the first signal SIN+.

One method to determine R1, R2, R3 and R4 is to use an equation (1): Rs,k=Rs_total/(1+tan θk), wherein Rs,k is an accumulated resistance in Table I, θk is a delay angle (or phase) in Table I. In Table I, Rs_total=100000 as an example. It is appreciated that when a value of the Rs_total is changed, R1 to R4 are also changed.

TABLE I

| | Accumulated | |
|---|---|---|
| Delay Angle θk | Resistance | Resistance |
| 0 | 10000 | |
| 22.5 | 7071.07 | R1 = 10000 − 7071.07 = 2928.93Ω |
| 45 | 5000 | R2 = 7071.07 − 5000 = 2071.07Ω |
| 67.5 | 2928.93 | R3 = 5000 − 2928.93 = 2071.07Ω |
| 90 | 0 | R4 = 2928.93 − 0 = 2928.93Ω |

It is seen from FIG. 6 that each of the first resistor string 61, the second resistor string 62, the third resistor string 63 and the fourth string 64 respectively includes 5 tap-out nodes (e.g., shown as N1, N2, N3, N4 and N5) located at one end of R1, R2, R3 and R4. Each resistor is connected between two tap-out nodes. A total number of 4×5 tape-out nodes are included in the phase shifter circuit 600. Each tape-out node is connected to one switching device, e.g., shown as SA, SB, SC, SD and SE.

In FIG. 6, when the switching devices SA are conducted, tape-out signals from the first, second, third and fourth resistor strings 61 to 64 have no phase delay (i.e. outputting 0-degree phase-corrected signals); when the switching devices SB are conducted, tape-out signals from the first, second, third and fourth resistor strings 61 to 64 have 22.5° phase delay (i.e. outputting 22.5-degree phase-corrected signals); when the switching devices SC are conducted, tape-out signals from the first, second, third and fourth resistor strings 61 to 64 have 45° phase delay (i.e. outputting 45-degree phase-corrected signals); when the switching devices SD are conducted, tape-out signals from the first, second, third and fourth resistor strings 61 to 64 have 67.5° phase delay (i.e. outputting 67.5-degree phase-corrected signals); and when the switching devices SE are conducted, tape-out signals from the first, second, third and fourth resistor strings 61 to 64 have 90° phase delay (i.e. outputting 90-degree phase-corrected signals).

That is, the switching devices SA, SB, SC, SD and SE are used to couple the attenuation circuits 65 to 68 to one tape-out node of the corresponding resistor strings 61 to 64 to cause the resistor strings 61 to 64 to output the 0-degree phase-corrected signal, the 22.5-degree phase-corrected signal, the 45-degree phase-corrected signal, the 67.5-degree phase-corrected signal or the 90-degree phase-corrected signal.

However, because input signals (i.e. two of the first to fourth signals) go through different resistors of the resistor strings 61 to 64, the phase-corrected signals outputted from the resistor strings 61 to 64 are attenuated differently corresponding to different degrees of phase delay. Referring to FIG. 7, if it is assumed that a peak-to-peak value of 45-degree phase-corrected signal is equal to 1 volt (e.g., between 2 volts and 3 volts as shown in FIG. 7) as a reference, peak-to-peak values of other phase-corrected signals are shown in Table II. It is appreciated that the reference is not limited to be set as 1 volt.

TABLE II

| Phase shift (degree) | Peak-to-peak (Vpp) |
|---|---|
| 0 | 1.414 |
| 22.5 | 1.082 |
| 45 | 1 |
| 67.5 | 1.082 |
| 90 | 1.414 |

To compensate the amplitude attenuation caused by the resistor strings 61 to 64, the present disclosure further provides an attenuation circuit (e.g., shown as 65 to 68) connected behind each resistor strings 61 to 64, respectively.

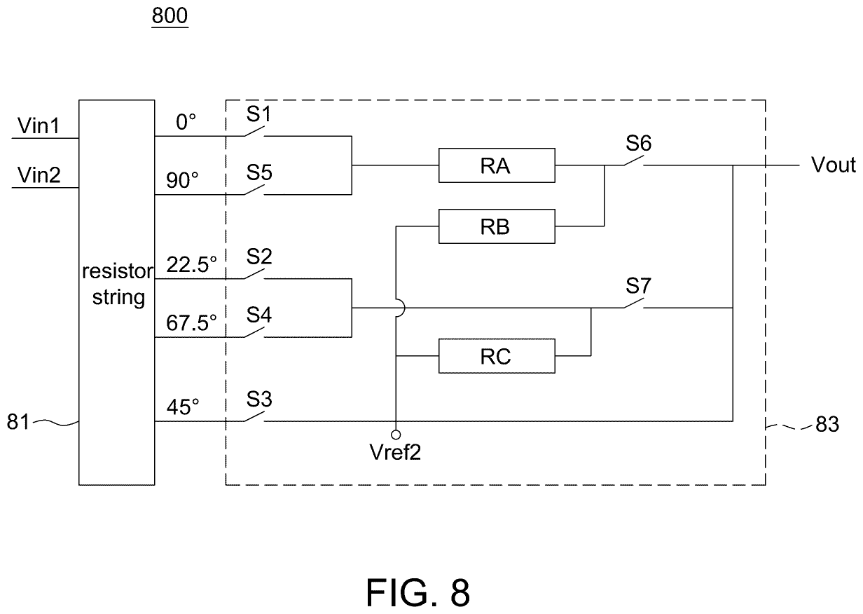

Please refer to 8, it is a schematic diagram of a phase shifter circuit 800 according to a first embodiment of the present disclosure including a phase-delay resistor string 81 (abbreviated as resistor string) and an attenuation circuit 83. The resistor string 81 represents the first, second, third and fourth resistor strings 61 to 64 shown in FIG. 6, and the resistor string 81 receives a first input signal Vin1 and a second input signal Vin2, wherein Vin1 and Vin2 are one couple of SIN+ and COS+, SIN− and cos−, COS+ and SIN−, COS− and SIN+ as shown in FIG. 6. The attenuation circuit 83 represents the first, second, third and fourth attenuation circuits 65 to 68 as shown in FIG. 6. Connections of the first, second, third and fourth resistor strings 61 to 64 respectively with the first, second, third and fourth attenuation circuits 65 to 68 are identical, and thus FIG. 8 only shows one resistor string 81 connected with one attenuation circuit 83 to indicate the connection between the first resistor string 61 with the first attenuation circuit 65, the connection between the second resistor string 62 with the second attenuation circuit 66, the connection between the third resistor string 63 with the third attenuation circuit 67, the connection between the fourth resistor string 64 with the fourth attenuation circuit 68 shown in FIG. 6.

The attenuation circuit 83 includes a first resistor RA, a second resistor RB and a third resistor RC. In one aspect, corresponding to the resistance of R1 to R4 in Table I, the first resistor RA=4140 ohm, the second resistor RB=10000 ohm, and the third resistor RC=25257.41 ohm. Similarly, when a value of the Rs_total is changed, values of RA to RC are also changed.

In the first embodiment, a first end (e.g., left end shown in FIG. 8) of the first resistor RA is coupled to the resistor string 81 to receive a 0-degree phase-corrected signal via a first switch S1 or to receive a 90-degree phase-corrected signal via a fifth switch S5, and a second end (e.g., right end shown in FIG. 8) of the first resistor RA is coupled to an output terminal (e.g., shown as Vout in FIG. 8) of the attenuation circuit 83 via a sixth switch S6. A first end (e.g., left end shown in FIG. 8) of the second resistor RB is coupled to a reference voltage (e.g., shown as Vref2 in FIG. 8), and a second end (e.g., right end shown in FIG. 8) of the second resistor RB is coupled to the output terminal Vout via the sixth switch S6. A first end (e.g., left end shown in FIG. 8) of the third resistor RC is coupled to the reference voltage Vref2, and a second end (e.g., right end shown in FIG. 8) of the third resistor RC is coupled to the output terminal Vout via a seventh switch S7.

The output terminal Vout of the attenuation circuit 83 is coupled to the resistor string 81 to receive a 45-degree phase-corrected signal via a third switch S3 without passing through the first resistor RA, the second resistor RB or the third resistor RC. The attenuation circuit 83 is used to receive a 22.5-degree phase-corrected signal from the resistor string 81 via a second switch S2 or to receive a 67.5-degree phase-corrected signal from the resistor string 81 via a fourth switch S4.

In one aspect, the reference voltage Vref2 is a center voltage (e.g., 2.5V shown in FIG. 7) of a peak-to-peak voltage of the 0-degree phase-corrected signal, the 22.5-degree phase-corrected signal, the 45-degree phase-corrected signal, the 67.5-degree phase-corrected signal or the 90-degree phase-corrected signal.

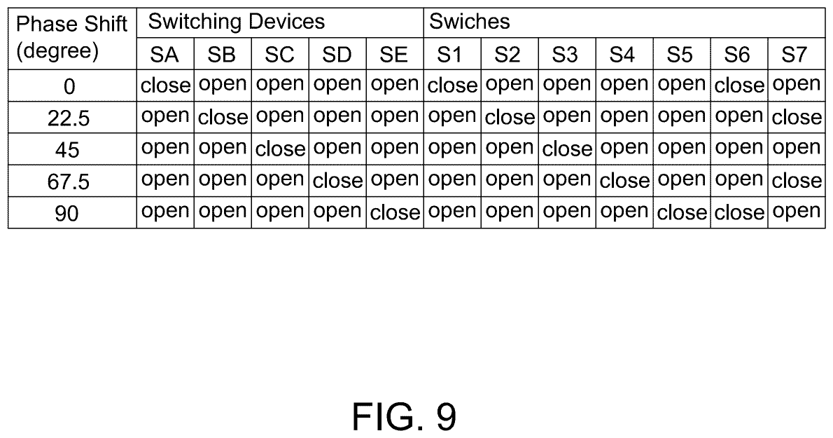

Please refer to FIG. 9, it is a schematic diagram of switch operation of the phase shifter circuit, including the switching devices SA to SE in FIG. 6 and the switches S1 to S7 in FIG. 8, according to the first embodiment of the present disclosure. In FIG. 9, a switch and a switching device being conducted is shown as “close”, and a switch and a switching device not being conducted is shown as “open”. It is seen from FIG. 9 that when one of the first switch S1, the second switch S2, the third switch S3, the fourth switch S4 and the fifth switch S5 is conducted, the rest of the first switch S1, the second switch S2, the third switch S3, the fourth switch S4 and the fifth switch S5 are not conducted; when the third switch S3 is conducted, the sixth switch S6 and the seventh switch S7 are not conducted; and the sixth switch S6 and the seventh switch S7 are not conducted at the same time. Vout is shown in FIG. 10.

FIG. 10 is a schematic diagram of phase-corrected signals after the amplitude compensation by the phase shifter circuit according to the first embodiment and the second embodiment (described below) of the present disclosure. It is seen that the 0-degree, 22.5-degree, 45-degree, 67.5-degree and 90-degree phase-corrected signals have substantially identical amplitudes.

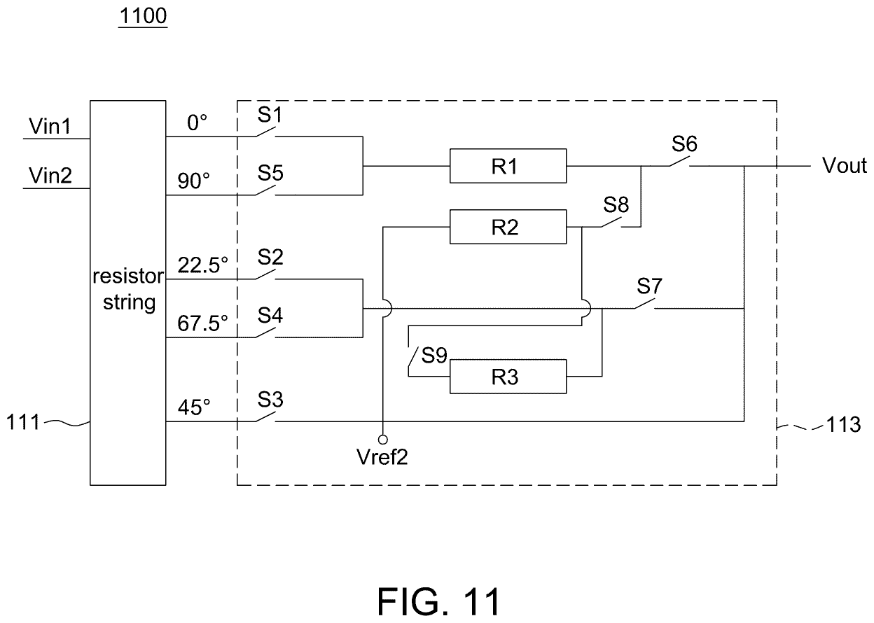

Please refer to FIG. 11, it is a schematic diagram of a phase shifter circuit 1100 according to a second embodiment of the present disclosure including a phase-delay resistor string 111 (abbreviated as resistor string) and an attenuation circuit 113. The resistor string 111 represents the first, second, third and fourth resistor strings 61 to 64 shown in FIG. 6, and the resistor string 111 receives a first input signal Vin1 and a second input signal Vin2, wherein Vin1 and Vin2 are one couple of SIN+ and COS+, SIN− and COS−, COS+ and SIN−, COS− and SIN+ as shown in FIG. 6. The attenuation circuit 113 represents the first, second, third and fourth attenuation circuits 65 to 68 as shown in FIG. 6. Connections of the first, second, third and fourth resistor strings 61 to 64 respectively with the first, second, third and fourth attenuation circuits 65 to 68 are identical, and thus FIG. 11 only shows one resistor string 111 connected with one attenuation circuit 113 to indicate the connection between the first resistor string 61 with the first attenuation circuit 65, the connection between the second resistor string 62 with the second attenuation circuit 66, the connection between the third resistor string 63 with the third attenuation circuit 67, the connection between the fourth resistor string 64 with the fourth attenuation circuit 68 as shown in FIG. 6.

The second embodiment is to further reduce the resistance being arranged in the attenuation circuit 113. The attenuation circuit 113 also includes a first resistor RA, a second resistor RB and a third resistor RC. In one aspect, corresponding to the resistance of R1 to R4 in Table I, the first resistor RA=4140 ohm, the second resistor RB=10000 ohm, and the third resistor RC=15257.41 ohm. Similarly, when a value of the Rs_total is changed, values of RA to RC are also changed.

In the second embodiment, a first end (e.g., left end shown in FIG. 11) of the first resistor RA is coupled to the resistor string 111 to receive a 0-degree phase-corrected signal via a first switch S1 or to receive a 90-degree phase-corrected signal via a fifth switch S5, and a second end (e.g., right end shown in FIG. 11) of the first resistor RA is coupled to an output terminal (e.g., shown as Vout in FIG. 11) of the attenuation circuit 113 via a sixth switch S6. A first end (e.g., left end shown in FIG. 11) of the second resistor RB is coupled to a reference voltage (e.g., shown as Vref2 in FIG. 11), and a second end (e.g., right end shown in FIG. 11) of the second resistor RB is coupled to the output terminal Vout via an eighth switch S8 and the sixth switch S6. A first end (e.g., left end shown in FIG. 11) of the third resistor RC is coupled to the second end of the second resistor RB via a ninth switch S9, and a second end (e.g., right end shown in FIG. 11) of the third resistor RC is coupled to the output terminal Vout via a seventh switch S7.

The output terminal Vout of the attenuation circuit 113 is coupled to the resistor string 111 to receive a 45-degree phase-corrected signal via a third switch S3 without passing through the first resistor RA, the second resistor RB or the third resistor RC. The attenuation circuit 113 is used to receive a 22.5-degree phase-corrected signal from the resistor string 111 via a second switch S2 or to receive a 67.5-degree phase-corrected signal from the resistor string 111 via a fourth switch S4.

In one aspect, the reference voltage Vref2 is a center voltage (e.g., 2.5V shown in FIG. 7) of a peak-to-peak voltage of the 0-degree phase-corrected signal, the 22.5-degree phase-corrected signal, the 45-degree phase-corrected signal, the 67.5-degree phase-corrected signal or the 90-degree phase-corrected signal.

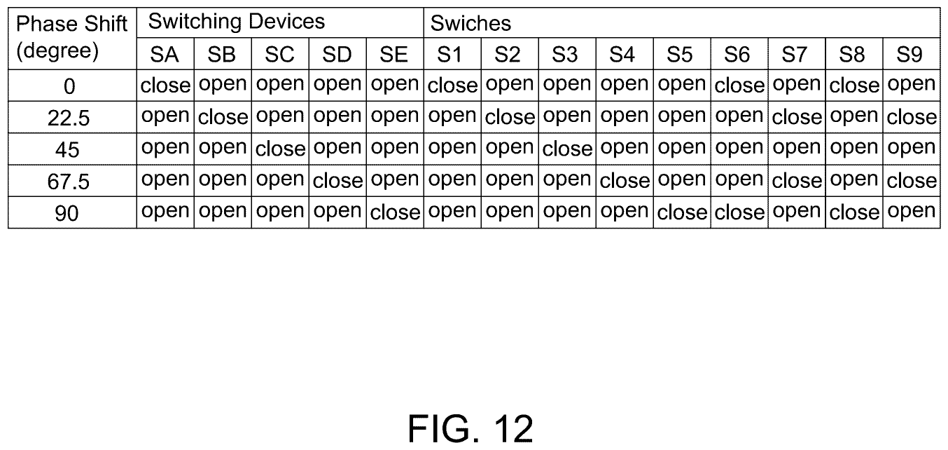

Please refer to FIG. 12, is a schematic diagram of switch operation of the phase shifter circuit, including the switching devices SA to SE in FIG. 6 and the switches S1 to S9 in FIG. 11, according to the second embodiment of the present disclosure. In FIG. 12, a switch or a switching device being conducted is shown as “close”, and a switch or a switching device not being conducted is shown as “open”. It is seen from FIG. 12 that when one of the first switch S1, the second switch S2, the third switch S3, the fourth switch S4 and the fifth switch S5 is conducted, the rest of the first switch S1, the second switch S2, the third switch S3, the fourth switch S4 and the fifth switch S5 are not conducted; when the third switch S3 is conducted, the sixth switch S6, the seventh switch S7, the eighth switch S8 and the ninth switch S9 are not conducted; when the sixth switch S6 and eighth switch S8 are conducted, the seventh switch S7 and ninth switch S9 are not conducted; and when the seventh switch S7 and ninth switch S9 are conducted, the sixth switch S6 and eighth switch S8 are not conducted. Vout is also shown in FIG. 10.

It should be mentioned that although FIGS. 8 and 11 show that the 0-degree phase-corrected signal and the 90-degree phase-corrected signal are coupled to the attenuation circuit 83/113 via two switches S1 and S5, the present disclosure is not limited thereto. In another aspect, the 0-degree phase-corrected signal and the 90-degree phase-corrected signal are coupled to the attenuation circuit 83/113 via a single switch or via a multiplexer to replace the two switches S1 and S5.

It should be mentioned that although FIGS. 8 and 11 show that the 22.5-degree phase-corrected signal and the 67.5-degree phase-corrected signal are coupled to the attenuation circuit 83/113 via two switches S2 and S4, the present disclosure is not limited thereto. In another aspect, the 22.5-degree phase-corrected signal and the 67.5-degree phase-corrected signal are coupled to the attenuation circuit 83/113 via a single switch or via a multiplexer to replace the two switches S2 and S4.

It should be mentioned that although FIGS. 8 and 11 show that the first resistor RA, the second resistor RB and the third resistor RC are respectively formed by a single resistor component, the present disclosure is not limited thereto. In another aspect, the first resistor RA, the second resistor RB and the third resistor RC are respectively formed by multiple resistor components connected in series or in parallel.

The present disclosure does not adopt amplifier to compensate amplitude differences between phase-corrected signals such that the power consumption during operation and occupied silicon area can be effectively decreased.

As mentioned above, it is known that there is a phase shift between incremental AB signals and an index signal or between incremental AB signals due to spatial offsets of components of an optical encoder. Although the phase shift can be compensated using phase-delay resistors, amplitudes between phase-corrected signals are different. Accordingly, the present disclosure further provides a phase shifter circuit (e.g., FIGS. 8 and 11) and an operating method of the phase shifter circuit (e.g., FIGS. 9 and 12). In the present disclosure, an attenuation circuit having three resistors is used to equalize phase-corrected signals outputted by a phase-delay resistor strings.

Although the disclosure has been explained in relation to its preferred embodiment, it is not used to limit the disclosure. It is to be understood that many other possible modifications and variations can be made by those skilled in the art without departing from the spirit and scope of the disclosure as hereinafter claimed.

1. A phase shifter circuit of an optical encoder, the phase shifter circuit being configured to receive a first signal, a second signal, a third signal and a fourth signal sequentially having a 90-degree phase shift, and comprising:
a resistor string, comprising 4 resistors cascaded together, and two ends of the resistor string being configured to receive two signals among the first to fourth signals, respectively; and
an attenuation circuit, comprising a first resistor, a second resistor and a third resistor, wherein
a first end of the first resistor is coupled to the resistor string to receive a 0-degree phase-corrected signal via a first switch or to receive a 90-degree phase-corrected signal via a fifth switch, and a second end of the first resistor is coupled to an output terminal of the attenuation circuit via a sixth switch,
a first end of the second resistor is coupled to a reference voltage, and a second end of the second resistor is coupled to the output terminal via the sixth switch, and
a first end of the third resistor is coupled to the reference voltage, and a second end of the third resistor is coupled to the output terminal via a seventh switch.

2. The phase shifter circuit as claimed in claim 1, wherein the first signal and the third signal are sine wave signals, and the second signal and the fourth signal are cosine wave signals.

3. The phase shifter circuit as claimed in claim 2, wherein the two signals are the first and second signals, the third and fourth signals, the second and third signals, or the fourth and first signals.

4. The phase shifter circuit as claimed in claim 1, wherein the output terminal of the attenuation circuit is coupled to the resistor string to receive a 45-degree phase-corrected signal via a third switch without passing the first, second or third resistor.

5. The phase shifter circuit as claimed in claim 4, wherein the attenuation circuit is configured to receive a 22.5-degree phase-corrected signal from the resistor string via a second switch or to receive a 67.5-degree phase-corrected signal from the resistor string via a fourth switch.

6. The phase shifter circuit as claimed in claim 5, wherein the resistor string further comprises 5 switching devices configured to couple the attenuation circuit to one tape-out node of the resistor string to cause the resistor string to output the 0-degree phase-corrected signal, the 22.5-degree phase-corrected signal, the 45-degree phase-corrected signal, the 67.5-degree phase-corrected signal or the 90-degree phase-corrected signal.

7. The phase shifter circuit as claimed in claim 5, wherein
when one of the first switch, the second switch, the third switch, the fourth switch and the fifth switch is conducted, the rest of the first switch, the second switch, the third switch, the fourth switch and the fifth switch are not conducted, and
when the third switch is conducted, the sixth switch and the seventh switch are not conducted.

8. The phase shifter circuit as claimed in claim 5, wherein the sixth switch and the seventh switch are not conducted at the same time.

9. The phase shifter circuit as claimed in claim 5, wherein the reference voltage is a center voltage of a peak-to-peak voltage of the 0-degree phase-corrected signal, the 22.5-degree phase-corrected signal, the 45-degree phase-corrected signal, the 67.5-degree phase-corrected signal or the 90-degree phase-corrected signal.

10. A phase shifter circuit of an optical encoder, the phase shifter circuit being configured to receive a first signal, a second signal, a third signal and a fourth signal sequentially having a 90-degree phase shift, the phase shifter circuit comprising:
a resistor string, comprising 4 resistors cascaded together, and two ends of the resistor string being configured to receive two signals among the first to fourth signals, respectively; and
an attenuation circuit, comprising a first resistor, a second resistor and a third resistor, wherein
a first end of the first resistor is coupled to the resistor string to receive a 0-degree phase-corrected signal via a first switch or to receive a 90-degree phase-corrected signal via a fifth switch, and a second end of the first resistor is coupled to an output terminal of the attenuation circuit via a sixth switch,
a first end of the second resistor is coupled to a reference voltage, and a second end of the second resistor is coupled to the output terminal via an eighth switch and the sixth switch, and
a first end of the third resistor is coupled to the second end of the second resistor via a ninth switch, and a second end of the third resistor is coupled to the output terminal via a seventh switch.

11. The phase shifter circuit as claimed in claim 10, wherein the first signal and the third signal are sine wave signals, and the second signal and the fourth signal are cosine wave signals.

12. The phase shifter circuit as claimed in claim 11, wherein the two signals are the first and second signals, the third and fourth signals, the second and third signals, or the fourth and first signals.

13. The phase shifter circuit as claimed in claim 10, wherein the output terminal of the attenuation circuit is coupled to the resistor string to receive a 45-degree phase-corrected signal via a third switch without passing the first, second or third resistor.

14. The phase shifter circuit as claimed in claim 13, wherein the attenuation circuit is configured to receive a 22.5-degree phase-corrected signal from the resistor string via a second switch or to receive a 67.5-degree phase-corrected signal from the resistor string via a fourth switch.

15. The phase shifter circuit as claimed in claim 14, wherein the resistor string further comprises 5 switching devices configured to couple the attenuation circuit to one tape-out node of the resistor string to cause the resistor string to output the 0-degree phase-corrected signal, the 22.5-degree phase-corrected signal, the 45-degree phase-corrected signal, the 67.5-degree phase-corrected signal or the 90-degree phase-corrected signal.

16. The phase shifter circuit as claimed in claim 14, wherein
when one of the first switch, the second switch, the third switch, the fourth switch and the fifth switch is conducted, the rest of the first switch, the second switch, the third switch, the fourth switch and the fifth switch are not conducted, and
when the third switch is conducted, the sixth, seventh, eighth and ninth switches are not conducted.

17. The phase shifter circuit as claimed in claim 14, wherein
when the sixth and eighth switches are conducted, the seventh and ninth switches are not conducted, and
when the seventh and ninth switches are conducted, the sixth and eighth switches are not conducted.

18. The phase shifter circuit as claimed in claim 14, wherein the reference voltage is a center voltage of a peak-to-peak voltage of the 0-degree phase-corrected signal, the 22.5-degree phase-corrected signal, the 45-degree phase-corrected signal, the 67.5-degree phase-corrected signal or the 90-degree phase-corrected signal.

19. A phase shifter circuit of an optical encoder, the phase shifter circuit being configured to receive a first signal, a second signal, a third signal and a fourth signal sequentially having a 90-degree phase shift, the phase shifter circuit comprising:
four resistor strings, each comprising 4 resistors cascaded together, and two ends of each resistor string being configured to receive two signals among the first to fourth signals, respectively; and
four attenuation circuits, each comprising a first resistor, a second resistor and a third resistor, and each attenuation circuit being configured to attenuate amplitudes of a 0-degree phase-corrected signal, a 22.5-degree phase-corrected signal, a 67.5-degree phase-corrected signal or a 90-degree phase-corrected signal to be identical to a 45-degree phase-corrected signal outputted by the four resistor strings.

20. The phase shifter circuit as claimed in claim 19, wherein the first signal and the third signal are sine wave signals, and the second signal and the fourth signal are cosine wave signals.
